(19) United States
(12) Patent Application Publication
(10) Pub. No.: US 2022/0298057 A1
(43) Pub. Date: Sep. 22, 2022

(54) GLASS SUBSTRATE

(71) Applicant: NIPPON ELECTRIC GLASS CO., LTD., Otsu-shi, Shiga (JP)

(72) Inventor: Atsuki SAITO, Otsu-shi (JP)

(21) Appl. No.: 17/630,976

(22) PCT Filed: Jul. 28, 2020
(86) PCT No.: PCT/JP2020/028850

§ 371 Date: Jan. 28, 2022

(30) Foreign Application Priority Data
Aug. 14, 2019 (JP) 2019-148859

(51) Int. Cl. C03C 3/091; C03C 3/087; C03B 17/06

(52) U.S. Cl. CPC C03C 3/091; C03C 3/087; C03B 17/064; H01L 51/0096

(57) ABSTRACT

Provided is a glass substrate having low chargeability. A glass substrate contains, as a glass composition in terms of % by mass, 1.7 to less than 9% B₂O₃, 0.01% or less Li₂O, 0.001 to 0.03% Na₂O, 0.0001 to 0.007% K₂O, 0.0011 to 0.035% Na₂O+K₂O, and more than 0 to 0.4% SnO₂.

### TECHNICAL FIELD

The present invention relates to glass substrates and particularly relates to a glass substrate suitable for every type of substrate for display including an organic EL display.

### BACKGROUND ART

An organic EL display and like electronic devices are thin, excel in displaying videos, have less power consumption, and are therefore used in display application, such as a display for TV and a display for smartphone.

Glass substrates are widely used as substrates for organic EL displays. The glass substrates for this application are required to have mainly the following characteristics:

(1) For the purpose of preventing diffusion of alkali ions into a semiconductor material formed in a film in a heat treatment process, the glass substrate contains less alkali metal oxide;

(2) For the purpose of cost reduction, the glass substrate has excellent productivity and, particularly, excellent devitrification resistance and meltability;

(3) In a production process for p-Si/a-Si.TFT, the glass substrate less deforms due to thermal contraction;

(4) In the production process for p-Si/a-Si.TFT, the glass substrate has low chargeability; and

(5) The glass substrate has a smooth surface suitable for the production process for p-Si/a-Si.TFT.

### SUMMARY OF INVENTION

### Technical Problem

To be more specific about the above characteristics (4) and (5), because the glass substrate is an insulator, its contact with an exposure stage or the like in the production process for p-Si/a-Si.TFT may cause the glass substrate to become charged. This charging is one of major factors in the occurrence of a pitch difference of each deposited film for use in TFT pixels.

As described in the characteristic (5), in order to form a high-quality TFT, the surface is preferably smooth and the glass substrate for use as a display substrate, even a glass substrate using a floating process involving polishing, is required to have a surface quality of a considerable degree of smoothness close to a free surface. However, as the surface of the glass substrate is smoother, the glass substrate is more likely to become charged. In other words, there is a trade-off between the challenge associated with the characteristic (4) and the challenge associated with the characteristic (5).

Under present circumstances, in order to reduce charging, the exposure stage or the under surface of the glass substrate is roughened. However, even if the exposure stage is roughened, the roughened surface becomes smoothened after repeated use. On the other hand, in order to roughen the under surface of the glass substrate, it is necessary to subject the under surface to chemical etching or gas etching, which presents, for example, a problem that etch residue is mixed into a deposited film surface. In addition, the need to add these processes to the production process arises, which naturally leads to a cost increase.

Moreover, with recent thinning of display devices, yield reduction due to charging has become a major problem. The reason for this is that when the glass substrate is thinned, it fits in with the exposure stage or the like, so that the contact area between the glass substrate and the exposure stage or the like increases and, thus, the glass substrate more easily becomes charged.

In view of the foregoing, the present invention has an object of providing a glass substrate having low chargeability.

### Solution to Problem

The inventor has repeatedly conducted various experiments, resulting in the finding that the above technical challenge can be solved by strictly controlling the content of a trace of alkali oxide to be contained in the glass substrate, and proposes the finding as the present invention.

Specifically, a glass substrate according to the present invention contains, as a glass composition in terms of % by mass, 1.7 to less than 9% B₂O₃, 0.01% or less Li₂O, 0.001 to 0.03% Na₂O, 0.0001 to 0.007% K₂O, 0.0011 to 0.035% Na₂O+K₂O, and more than 0 to 0.4% SnO₂. Herein, “Na₂O+K₂O” means the total content of Na₂O and K₂O.

As for the charging phenomenon occurring in the process of TFT production, consideration should to be given to two points: initial charging occurring due to contact, peel-off, and so on and; later charge decay. The present invention is focused mainly on the reduction of initial charging. If the initial charging is significant, damage by electrostatic discharge or other defects may occur.

Alternatively, a glass substrate according to the present invention contains, as a glass composition in terms of % by mass, 0.01% or less Li₂O, 0.001 to 0.03% Na₂O, 0.0001 to 0.007% K₂O, and 0.0011 to 0.035% Na₂O+K₂O, and has a Young's Modulus of 80 GPa or more. The “Young's modulus” refers to a value measured by dynamic elastometry (the resonance method) based on JIS R1602.

Still alternatively, a glass substrate according to the present invention contains, as a glass composition in terms of % by mass, 0.01% or less Li₂O, 0.001 to 0.03% Na₂O, 0.0001 to 0.007% K₂O, 0.0011 to 0.035% Na₂O+K₂O, and 0.1% or less P₂O₅ and has a β-OH value of 0.18/mm or less. Herein, the “β-OH value” refers to a value determined by measuring the transmittance of glass with FT-IR and using the following equation.

β-OH value=(1/X)log(T₁/T₂)

X: glass thickness (mm)
T₁: transmittance (%) at a reference wavelength of 3846 cm⁻¹
T₂: minimum transmittance (%) at a hydroxyl group absorption wavelength of around 3600 cm⁻¹

Still alternatively, a glass substrate according to the present invention contains, as a glass composition in terms of % by mass, 0.01% or less Li₂O, 0.001 to 0.03% Na₂O, 0.0001 to 0.007% K₂O, and 0.0011 to 0.035% Na₂O+K₂O.

The glass substrate according to the present invention preferably further contains as the glass composition 0.1% by mass or less P₂O₅.

The glass substrate according to the present invention preferably has a 10 seconds later surface potential of 1000 V or less in terms of absolute value. Herein, the “10 seconds later surface potential” is the maximum of absolute values of surface potential in the glass substrate after alumina has been rubbed against the glass substrate for 10 seconds. A smaller absolute value of the 10 seconds later surface potential means less charge transfer and lower chargeability when the glass substrate comes into contact with the exposure stage or the like. A surface potential sensor or the like can be used for the measurement of the surface potential.

In the glass substrate according to the present invention, a degree of thermal contraction when subjected to a heat treatment at 500° C. for an hour is preferably 30 ppm or less. The “degree of thermal contraction when subjected to a heat treatment at 500° C. for an hour” is measured by the following method. First, as shown in FIG. 1(a), a strip sample G with 160 mm×30 mm is prepared as a measurement sample. On both end portions of the strip sample G in the longitudinal direction, respective markings M are formed at 20 to 40 mm distance from both edges of the strip sample G, using #1000 water-proof abrasive paper. Thereafter, as shown in FIG. 1(b), the strip sample G having the markings M formed thereon is folded and split into two pieces along a direction perpendicular to the markings M, thus making specimens Ga and Gb. Then, only one specimen Gb is subjected to a heat treatment of increasing the temperature from ordinary temperature to 500° C. at a rate of 5° C./min, holding the temperature at 500° C. for an hour, and then decreasing the temperature at a rate of 5° C./min. After the above heat treatment, as shown in FIG. 1 (c), the specimen Ga not subjected to the heat treatment and the specimen Gb subjected to the heat treatment are juxtaposed and, in this state, the amounts of misalignment (ΔL₁ and ΔL₂) between the markings M of the two specimens Ga and Gb are read with a laser microscope. Then, the degree of thermal contraction is calculated from the amounts of misalignment based on the equation below. Note that 10 mm in the equation below is an initial distance between the markings M. A high degree of thermal contraction causes a pitch difference between pixels of a TFT, which can cause a display defect.

Degree of thermal contraction(ppm)=[{ΔL₁(μm)+ΔL₂(μm)}×10³]/10(mm)

The glass substrate according to the present invention preferably has a strain point of 700° C. or higher. The “strain point” is a value measured based on the method described in ASTM C336 and C338. As the strain point is higher, thermal contraction is less likely to occur in the production process of a p-SiTFT.

In the glass substrate according to the present invention, an average coefficient of thermal expansion in a range from 30 to 380° C. is preferably 45×10⁻⁷/° C. or less. The “average coefficient of thermal expansion in a range from 30 to 380° C.” is a value measured with a dilatometer.

The glass substrate according to the present invention preferably has a Young's modulus of 80 GPa or more.

The glass substrate according to the present invention preferably has a liquidus viscosity of 10^{4.2} dPa·s or more. The “liquidus viscosity” is a value obtained by putting a glass powder having passed through a 30 mesh (500-μm openings) standard sieve and having been retained on a 50 mesh (300-μm openings) sieve into a platinum boat, holding the platinum boat in a temperature-gradient furnace for 24 hours, and determining, according to the well-known platinum ball pulling-up method, the viscosity at a temperature at which crystals (primary phase) precipitate.

In the glass substrate according to the present invention, a temperature at 10^{2.5} dPa·s is preferably 1590° C. or lower. The “temperature at 10^{2.5} dPa·s” is a value measured according to the platinum ball pulling-up method.

The glass substrate according to the present invention preferably has a β-OH value of 0.18/mm or less.

The glass substrate according to the present invention preferably has a thickness of 0.01 to 1.0 mm.

A method for producing a glass substrate according to the present invention includes producing the above-described glass substrate by an overflow downdraw method.

### Advantageous Effects of Invention

The present invention enables provision of a glass substrate having low chargeability.

### BRIEF DESCRIPTION OF DRAWINGS

FIG. 1 is a view for illustrating a method for measuring the degree of thermal contraction.

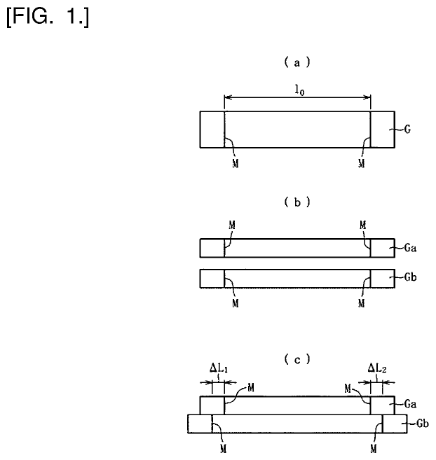

FIG. 2 is a graph showing the relationship between the total content of Na₂O and K₂O and the surface potential.

### DESCRIPTION OF EMBODIMENTS

A glass substrate according to the present invention contains, as a glass composition in terms of % by mass, 0.01% or less Li₂O, 0.001 to 0.03% Na₂O, 0.0001 to 0.007% K₂O, and 0.0011 to 0.035% Na₂O+K₂O. The reasons why the respective contents of the components are limited as above will be described below. In the descriptions of the respective contents of the components, % represents % by mass unless otherwise stated.

Li is the smallest element in alkali metals. Therefore, Li is likely to move in glass and, therefore, has a tendency to easily transfer electric charges and have high chargeability when the glass substrate comes into contact with the exposure stage or the like. In addition, because of ease of movement, Li is most likely to diffuse into a semiconductor material in the process of TFT production including heat treatment and thus tends to decrease the performance of the TFT. Therefore, the content of Li₂O is preferably 0.01% or less, more preferably 0.005% or less, still more preferably 0.001% or less, and particularly preferably 0.0005% or less.

Na is an element that easily transfers electric charges and increases the chargeability next to Li in alkali metals. In addition, Na is likely to diffuse into a semiconductor material in the process of TFT production next to Li. On the other hand, Na₂O is a component contained as an impurity in many kinds of raw materials. The use of a raw material less containing Na₂O leads to an increase in batch cost. In addition, if the content of Na₂O is too small in ohmically heating the glass, the glass is less likely to carry electric current. Therefore, a preferred upper limit to the content of Na₂O is 0.03%, more preferably 0.025%, still more preferably 0.02%, yet still more preferably 0.015%, even more preferably 0.014%, even still more preferably 0.013%, even yet still more preferably 0.012%, and particularly preferably 0.011%, and a preferred lower limit thereto is 0.001%, more preferably 0.002%, still more preferably 0.003%, yet still more preferably 0.004%, and particularly preferably 0.005%.

K has a larger ionic radius than Li and Na and is thus less likely to move in glass than Li and Na. However, because charging occurs in the most superficial area of the surface of the glass substrate, a large content of K, even if it is less likely to move, allows electric charges to easily move and thus increases the chargeability. In addition, even when the content of K₂O is small, inconveniences including an increase in batch cost and difficulty in carrying electric current are less likely to occur. On the other hand, K₂O is less likely to diffuse into a semiconductor material in the process of TFT production and thus less likely to decrease the performance of the TFT as compared to Li₂O and Na₂O. Therefore, a preferred upper limit to the content of K₂O is 0.007%, more preferably 0.006%, still more preferably 0.005%, yet still more preferably 0.004%, even more preferably 0.003%, and particularly preferably 0.002%, and a preferred lower limit thereto is 0.0001%, more preferably 0.0002%, still more preferably 0.0005%, yet still more preferably 0.0008%, and particularly preferably 0.001%.

As described above, Na₂O and K₂O are components that increase the chargeability. By restricting the total content of Na₂O and K₂O, it is possible to further decrease the chargeability. Specifically, a preferred upper limit to Na₂O+K₂O is 0.035%, more preferably 0.03%, still more preferably 0.027%, yet still more preferably 0.025%, even more preferably 0.02%, and particularly preferably 0.018%, and a preferred lower limit thereto is 0.0011%, more preferably 0.0012%, still more preferably 0.0015%, yet still more preferably 0.0018%, and particularly preferably 0.002%.

Table 1 shows the total contents of Na₂O and K₂O in glasses A, B, and C.

TABLE 1

| % by mass | A | B | C |
|---|---|---|---|
| Na₂O | 0.0294 | 0.0075 | 0.0198 |
| K₂O | 0.0019 | 0.0013 | 0.0011 |
| Na + K | 0.0313 | 0.0088 | 0.0209 |

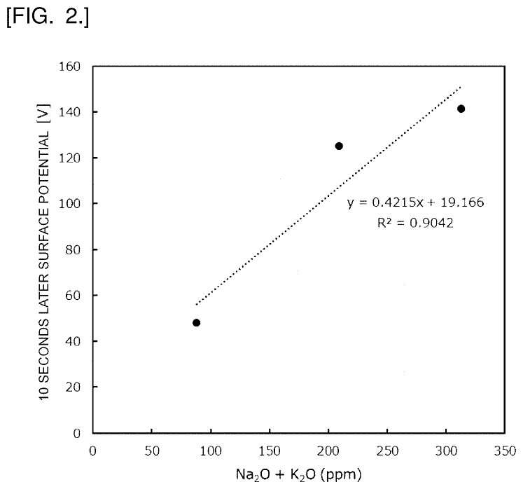

FIG. 2 is a graph showing the relationship between the total content of Na₂O and K₂O and the surface potential. It can be seen from FIG. 2 that as the total content of Na₂O and K₂O is smaller, the 10 seconds later surface potential becomes lower. It can also be seen that the glasses A, B, and C are glasses that can be used in the TFT process and the restriction of the total content of Na₂O and K₂O is very effective in order to decrease the chargeability.

In addition to the above components, for example, the following components may be contained in the glass substrate.

SiO₂ is a component that forms the glass network, raises the strain point, and increases the acid resistance. However, if the content of SiO₂ is large, the high-temperature viscosity becomes high to decrease the meltability and devitrified crystals of cristobalite or the like are likely to precipitate to increase the liquidus temperature. In addition, the etch rate in HF decreases. Therefore, the content of SiO₂ is preferably 55 to 70%, more preferably 58 to 65%, and particularly preferably 59 to 62%.

Al₂O₃ is a component that forms the glass network, raises the strain point, and increases the Young's modulus. However, if the content of Al₂O₃ is large, mullite and feldspar-based devitrified crystals are likely to precipitate to increase the liquidus temperature. Therefore, the content of Al₂O₃ is preferably 8 to 30%, more preferably 15 to 25%, still more preferably 17 to 23%, yet still more preferably 18 to 22%, even more preferably 18 to 21%, and particularly preferably 18 to 20%.

B₂O₃ is a component that increases the meltability and the devitrification resistance. However, B₂O₃ decreases the strain point and the Young's modulus, so that an increase in degree of thermal contraction and a pitch difference in the process of panel production are likely to occur. Therefore, a preferred upper limit to the content of B₂O₃ is less than 9%, more preferably 8% or less, still more preferably 7% or less, yet still more preferably 6% or less, even more preferably 5% or less, and particularly preferably 4% or less, and a preferred lower limit thereto is 0% or more, more preferably 0.5% or more, still more preferably 1% or more, yet still more preferably 1.5% or more, even more preferably 1.7% or more, even still more preferably 2% or more, further preferably 2.5% or more, and particularly preferably 3% or more.

MgO is a component that decreases the high-temperature viscosity to increase the meltability and increases the Young's modulus. However, if the content of MgO is large, this promotes precipitation of mullite crystals, crystals derived from Mg and Ba, and cristobalite crystals. In addition, the strain point is significantly decreased. Therefore, the content of MgO is preferably 0 to 10%, more preferably 2 to 6%, still more preferably 2 to 5%, yet still more preferably 2.5 to 5%, and particularly preferably 2.5 to 4.5%.

CaO is a component that decreases the high-temperature viscosity, without decreasing the strain point, to significantly increase the meltability. In addition, CaO is a component that decreases the raw material cost because a raw material for inducing the formation of CaO is relatively inexpensive in alkaline earth metal oxides. CaO is also a component that increases the Young's modulus. Furthermore, CaO has the effect of preventing precipitation of the above-described devitrified crystals containing Mg. However, if the content of CaO is large, anorthite devitrified crystals are likely to precipitate and the density is likely to increase. Therefore, the content of CaO is preferably 0 to 10%, more preferably 2 to 8%, still more preferably 3 to 7%, yet still more preferably 3.5 to 6%, and particularly preferably 3.5 to 5.5%.

SrO is a component that prevents phase separation and increases the devitrification resistance. Furthermore, SrO is a component that decreases the high-temperature viscosity, without decreasing the strain point, to increase the meltability. However, if the content of SrO is large, feldspar-based devitrified crystals are likely to precipitate in a glass system containing much CaO and, thus, the devitrification resistance is likely to decrease. In addition, the density tends to increase and the Young's modulus tends to decrease. Therefore, the content of SrO is preferably 0 to 15%, more preferably 0 to 10%, still more preferably 0 to 5%, yet still more preferably 0 to 4%, even more preferably 0 to 3%, even still more preferably 0 to 2%, even yet still more preferably 0 to 1.5%, further preferably 0 to 1%, and particularly preferably 0 to less than 1%.

SrO/CaO is a component ratio important for balancing a high devitrification resistance and a low degree of thermal contraction. If SrO/CaO is high, there is a tendency that the degree of thermal contraction increases and the devitrification resistance decreases. Therefore, SrO/CaO is preferably 0 to 2, more preferably 0.1 to 1.5, still more preferably 0.1 to 1.0, yet still more preferably 0.1 to 0.5, and particularly preferably 0.1 to 0.2. Herein, “SrO/CaO” is a value obtained by dividing the content of SrO by the content of CaO.

BaO is a component that is, in alkaline earth metal oxides, highly effective to prevent precipitation of mullite-based and anorthite-based devitrified crystals. However, if the content of BaO is large, the density is likely to increase, the Young's modulus is likely to decrease, and the high-temperature viscosity becomes excessively high, so that the meltability is likely to decrease. Therefore, the content of BaO is preferably 0 to 15%, more preferably 6 to 12%, still more preferably 7 to 11%, yet still more preferably 8 to 10.7%, and particularly preferably 9 to 10.5%.

Alkaline earth metal oxides are very important components for increasing the strain point, the devitrification resistance, and the meltability. If the amount of alkaline earth metal oxides is small, the strain point increases, but it becomes difficult to prevent precipitation of Al₂O₃-based devitrified crystals. In addition, the high-temperature viscosity increases, so that the meltability is likely to decrease. On the other hand, if the amount of alkaline earth metal oxides is large, the meltability is improved, but the strain point is likely to decrease and the liquidus viscosity may decrease because of a decrease in high-temperature viscosity. Therefore, MgO+CaO+SrO+BaO is preferably 10 to 40%, more preferably 16 to 20%, still more preferably 17 to 20%, yet still more preferably 17 to 19.5%, and particularly preferably 18 to 19.3%. Herein, “MgO+CaO+SrO+BaO” means the total content of MgO, CaO, SrO, and BaO.

ZnO is a component that increases the meltability, but a large content thereof makes the glass easily devitrifiable and makes it likely that the strain point decreases. Therefore, the content of ZnO is preferably 0 to 5%, more preferably 0 to 3%, still more preferably 0 to 0.5%, and particularly preferably 0 to 0.2%.

ZrO₂, Y₂O₃, Nb₂O₅, and La₂O₃ function to increase the strain point, the Young's modulus, and so on. However, if the content of each of these components is large, the density is likely to increase. Therefore, the content of each of ZrO₂, Y₂O₃, Nb₂O₅, and La₂O₃ is preferably 0 to 5%, more preferably 0 to 3%, still more preferably 0 to 1%, yet still more preferably 0 to less than 0.1%, and particularly preferably 0 to less than 0.05%.

P₂O₅ is a component that is likely to diffuse into a semiconductor material in the process of TFT production and thus tends to decrease the performance of the TFT. Therefore, the content of P₂O₅ is preferably 0.1% or less and particularly preferably 0.05% or less.

Without impairing the glass characteristics, F₂, Cl₂, SO₃, C or metal powder of Al, Si or so on may be added as a clarifying agent up to 5%. Alternatively, CeO₂ or so on may be added as a clarifying agent up to 1%.

SnO₂ is a component that has a good clarification effect in a high temperature range, increases the strain point, and decreases the high-temperature viscosity. However, if the content of SnO₂ is large, devitrified crystals of SnO₂ are likely to precipitate. Therefore, the content of SnO₂ is preferably more than 0 to 0.4%, more preferably 0.02 to 0.3%, and particularly preferably 0.1 to 0.25%.

As₂O₃ and Sb₂O₃ are effective as a clarifying agent, and the glass substrate according to the present invention is not intended to completely exclude the introduction of these components, but preferably uses these components as few as possible from an environmental perspective. In addition, a large content of As₂O₃ in the glass tends to cause a decrease in solarization resistance. Therefore, the content of As₂O₃ is preferably 0.1% or less and the glass substrate is particularly preferably substantially free of As₂O₃. Herein, “substantially free of As₂O₃” refers to the case where the content of As₂O₃ in the glass composition is less than 0.05%. On the other hand, the content of Sb₂O₃ is preferably 0.2% or less and more preferably 0.1% or less, and the glass substrate is particularly preferably substantially free of Sb₂O₃. Herein, “substantially free of Sb₂O₃” refers to the case where the content of Sb₂O₃ in the glass composition is less than 0.05%.

Fe₂O₃ is a component that is difficult to avoid being mixed as an impurity derived from a glass raw material into the glass substrate. Therefore, the introduction of Fe₂O₃ component cannot completely be excluded. Because Fe₂O₃ can function as a clarifying agent, it may be positively contained in the glass substrate. However, the glass according to the present invention preferably contains Fe₂O₃ as few as possible in order to keep the transmittance in the ultraviolet range as high as possible. When the transmittance in the ultraviolet range is kept at a high value, the efficiency in the use of ultraviolet range laser in a customer's process can be increased. Specifically, the content of Fe₂O₃ in the glass composition is 0.020% or less, preferably 0.015% or less, more preferably 0.011% or less, and particularly preferably 0.010% or less.

Cl has the effect of promoting melting of low-alkali glass. When Cl is added to the glass composition, the melting temperature can be lowered and the effect of the clarifying agent can be promoted. In addition, Cl has the effect of decreasing the β-OH value of molten glass. On the other hand, if the content of Cl is large, the strain point is likely to decrease. Therefore, the content of Cl is preferably 0.5% or less and particularly preferably 0.001 to 0.2%. As a raw material for inducing Cl, for example, a chloride of an alkaline earth metal oxide, such as strontium chloride, or aluminum chloride can be used.

The glass substrate according to the present invention preferably has the following glass characteristics.

The 10 seconds later surface potential is preferably 1000 V or less, more preferably 900 V or less, still more preferably 800 V or less, yet still more preferably 700 V or less, even more preferably 600 V or less, even still more preferably 500 V or less, even yet still more preferably 400 V or less, further preferably 300 V or less, still further preferably 200 V or less, and particularly preferably 100 V or less. Thus, even when coming into contact with the exposure stage or the like, the glass substrate is less likely to cause charge transfer and is therefore likely to have low chargeability.

The degree of thermal contraction of the glass substrate when subjected to a heat treatment at 500° C. for an hour is preferably 30 ppm or less, more preferably 20 ppm or less, and particularly preferably 15 ppm or less. Thus, the glass substrate is less likely to cause a pattern mismatch or like defects. However, if the degree of thermal contraction is too low, the production efficiency of the glass substrate is likely to decrease. Therefore, the degree of thermal contraction is preferably not less than 1 ppm, more preferably not less than 2 ppm, still more preferably not less than 3 ppm, yet still more preferably not less than 4 ppm, and particularly preferably not less than 5 ppm.

The strain point is preferably 700° C. or higher, more preferably 705° C. or higher, and particularly preferably 710° C. or higher. If the strain point is low, the glass substrate is likely to thermally contract in the production process. The upper limit to the strain point is not particularly limited, but is preferably not higher than 850° C. in consideration of the burden on production facilities.

The average coefficient of thermal expansion of the glass substrate in a temperature range from 30 to 380° C. is preferably 45×10⁻⁷/° C. or less, more preferably 34×10⁻⁷° C. to 43×10⁻⁷/° C., and particularly preferably 38×10⁻⁷/° C. to 41×10⁻⁷/° C. If the average coefficient of thermal expansion thereof in a temperature range from 30 to 380° C. is out of the above ranges, the glass substrate does not match in coefficient of thermal expansion with surrounding members, so that peel-off of the surrounding members and warpage of the glass substrate are likely to occur. Furthermore, if this value is large, a pitch difference due to temperature variations during the heat treatment is likely to occur.

As the Young's modulus is higher, the glass substrate is less likely to deform. With the recent increasing definition of organic EL and the like, the thickness of metallic wires is increasing in order to prevent the sheet resistance and, thus, the glass substrate is being required to have higher stiffness. Therefore, the Young's modulus is preferably 78 GPa or more, more preferably 79 GPa or more, and particularly preferably 80 GPa or more.

Furthermore, the specific Young's modulus is preferably more than 29.5 GPa/g·cm⁻³, more preferably 30 GPa/g·cm⁻³ or more, still more preferably 30.5 GPa/g·cm³ or more, yet still more preferably 31 GPa/g·cm⁻³ or more, even more preferably 31.5 GPa/g·cm⁻³ or more, and particularly preferably 32 GPa/g·cm⁻³ or more.

The liquidus temperature is preferably lower than 1300° C., more preferably 1280° C. or lower, still more preferably 1250° C. or lower, yet still more preferably 1230° C. or lower, and particularly preferably 1220° C. or lower. If the liquidus temperature is high, devitrified crystals are produced during glass forming by the overflow downdraw method, so that the productivity of the glass substrate is likely to decrease.

The liquidus viscosity is preferably 10^{4.2} dPa·s or higher, more preferably 10^{4.4} dPa·s or higher, still more preferably 10^{4.6} dPa·s or higher, yet still more preferably 10^{4.8} dPa·s or higher, and particularly preferably 10^{5.0} dPa·s or higher. If the liquidus viscosity is low, devitrified crystals are produced during glass forming by the overflow downdraw method, so that the productivity of the glass substrate is likely to decrease.

The temperature at a high-temperature viscosity of 10^{2.5} dPa·s is preferably 1660° C. or lower, more preferably 1640° C. or lower, still more preferably 1630° C. or lower, yet still more preferably 1620° C. or lower, even more preferably 1600° C. or lower, and particularly preferably 1590° C. or lower. If the temperature at a high-temperature viscosity of 10^{2.5} dPa·s is high, the glass is difficult to melt, so that the production cost of the glass substrate rises.

Water in the glass, like alkali metal elements, extremely weakens the glass network to create portions having a strong polarity in the glass structure. Therefore, in order to reduce the chargeability, it is effective to reduce the water content in the glass. In addition, when the amount of water in the glass is reduced, it is possible to not only increase the strain point, but also considerably decrease the degree of thermal contraction. Therefore, the β-OH value is preferably 0.30/mm or less, more preferably 0.25/mm or less, still more preferably 0.20/mm or less, yet still more preferably 0.18/mm or less, and particularly preferably 0.15/mm or less. If the β-OH value is too large, the chargeability is likely to increase and the strain point is likely to decrease. On the other hand, if the β-OH value is too small, the meltability is likely to decrease. Therefore, the β-OH value is preferably not less than 0.01/mm and particularly preferably not less than 0.02/mm.

Furthermore, when the sum of the value of the alkali content and the β-OH value is restricted, it is possible to further reduce the chargeability. Specifically, (Na₂O+K₂O)+β-OH is preferably less than 0.2, more preferably less than 0.15, and particularly preferably less than 0.13. Note that “(Na₂O+K₂O)+β-OH” means the sum of the total content of Na₂O and K₂O and the β-OH value.

Examples of the method for reducing the β-OH value include the following methods: (1) selection of a raw material having a low water content; (2) addition of a component (such as Cl or SO₃) for reducing the amount of water in the glass; (3) reduction of the amount of water in a furnace atmosphere; (4) N₂ bubbling in molten glass; (5) adoption of a small melting furnace; (6) increase of the flow rate of molten glass; and (7) use of electrical melting process.

Herein, the “β-OH value” refers to a value determined by measuring the transmittance of glass with FT-IR and using the following equation.

β-OH value=(1/X)log(T₁/T₂)

X: glass thickness (mm)
T₁: transmittance (%) at a reference wavelength of 3846 cm⁻¹
T₂: minimum transmittance (%) at a hydroxyl group absorption wavelength of around 3600 cm⁻¹

The glass substrate according to the present invention preferably has the shape of a flat sheet and has an overflow merging plane in the middle thereof in the thickness direction. In other words, the glass substrate is preferably formed into the shape by the overflow downdraw method. The overflow downdraw method is a method for forming glass into a flat sheet by overflowing molten glass from both sides of a wedge-shaped refractory and allowing the overflowed molten glass to merge at the bottom end of the wedge shape and concurrently drawing it downward. In the overflow downdraw method, the surfaces of the molten glass that will form the surfaces of a glass substrate do not contact the refractory and are formed, in a free-surface state, into shape. Therefore, an unpolished glass substrate having a good surface quality can be produced at low cost and the glass substrate can be easily increased in area and easily thinned.

The glass substrate can be formed into a shape by, except for the overflow downdraw method, for example, the slot down method, the redraw method, the float method or the roll-out method.

No particular limitation is placed on the thickness of the glass substrate, but, in order to facilitate the weight reduction of a device, the thickness is preferably 1.0 mm or less, more preferably 0.5 mm or less, still more preferably 0.4 mm or less, yet still more preferably 0.35 mm or less, and particularly preferably 0.3 mm or less. However, if the thickness is too small, the glass substrate easily bends. Therefore, the thickness of the glass substrate is preferably not less than 0.001 mm and particularly preferably not less than 0.01 mm. The thickness can be adjusted by the flow rate, the drawing speed, and so on during production of the glass.

Next, a description will be given of a method for producing a glass substrate.

A production process for a glass substrate generally includes a melting step, a clarification step, a feeding step, a stirring step, and a forming step. The melting step is the step of melting a glass batch obtained by formulating glass raw materials, thus obtaining a molten glass. The clarification step is the step of clarifying the molten glass obtained in the melting step according to the action of a clarifying agent or the like. The feeding step is the step of transferring the molten glass from one step to the next. The stirring step is the step of stirring the molten glass to homogenize it. The forming step is the step of forming the molten glass into a flat sheet-shaped glass. If necessary, any step other than the above steps, for example, a conditioning step for controlling the molten glass to a condition suitable for forming, may be adopted after the stirring step.

In industrially producing a conventional low-alkali glass, the glass is generally melted by heating with combustion flame of a burner. The burner is generally disposed above a melting furnace and uses fossil fuel as fuel, specifically, liquid fuel, such as heavy oil, or gaseous fuel, such as LPG. Combustion flame can be obtained by mixing fossil fuel with oxygen gas. However, in this method, a large amount of water is mixed into the molten glass during melting, so that the β-OH value is likely to increase. Therefore, in producing the glass according to the present invention, ohmic heating with a heating electrode is preferably performed and the glass batch is preferably melted, not by heating with combustion flame of a burner, but by ohmic heating with a heating electrode. Thus, water is less likely to be mixed into the molten glass during melting, which makes it likely that the β-OH value decreases. In addition, when ohmic heating with a heating electrode is performed, the amount of energy per mass required to obtain molten glass decreases and the amount of volatile during melting decreases, so that the environmental burden can be reduced.

Ohmic heating with a heating electrode is preferably performed by applying an alternating voltage to the heating electrode provided on the bottom or side wall of the melting furnace so that the heating electrode comes into contact with molten glass in the melting furnace. A material for use as the heating electrode preferably has thermal resistance and corrosion resistance against molten glass. For example, tin oxide, molybdenum, platinum or rhodium can be used as the material. Molybdenum is particularly preferred.

The glass substrate according to the present invention is made of low-alkali glass not containing much alkali metal oxide and, therefore, has a high electrical resistivity. Hence, when ohmic heating with a heating electrode is applied to low-alkali glass, an electric current flows through not only the molten glass, but also a refractory forming the melting furnace, so that the refractory forming the melting furnace may be damaged early. To prevent this, a zirconia-based refractory having a high electrical resistivity, particularly zirconia electrocast bricks, are preferably used as a refractory in the furnace and the content of ZrO₂ in the zirconia-based refractory is preferably 85% by mass or more and particularly preferably 90% by mass or more.

### Examples

Hereinafter, the present invention will be described with reference to examples.

Table 2 shows examples (sample Nos. 1 to 10) of the present invention. In the table, “N.A.” means that the sample has not been measured in terms of relevant item.

TABLE 2

| % by mass | 1 | 2 | 3 | 4 | 5 | 6 | 7 | 8 | 9 | 10 |
|---|---|---|---|---|---|---|---|---|---|---|
| SiO₂ | 59.7 | 59.0 | 62.6 | 60.8 | 61.2 | 64.1 | 61.9 | 61.4 | 61.4 | 61.0 |
| Al₂O₃ | 16.5 | 19.3 | 19.0 | 20.1 | 20.2 | 16.9 | 15.8 | 18.7 | 18.6 | 20.1 |
| B₂O₃ | 10.3 | 6.5 | 6.2 | 3.4 | 2.1 | 0.3 | 0.0 | 0.7 | 0.7 | 0.0 |
| MgO | 0.3 | 2.5 | 0.8 | 3.7 | 2.2 | 1.8 | 0.0 | 3.2 | 3.4 | 1.9 |
| CaO | 8.0 | 6.3 | 7.2 | 5.5 | 5.2 | 5.9 | 8.7 | 5.0 | 3.8 | 3.7 |
| SrO | 4.5 | 0.5 | 2.5 | 2.5 | 1.7 | 0.8 | 1.9 | 0.6 | 3.2 | 0.0 |
| BaO | 0.5 | 5.7 | 1.5 | 3.9 | 7.2 | 10.0 | 11.4 | 10.1 | 8.7 | 13.1 |
| TiO₂ | 0.00 | 0.00 | 0.00 | 0.00 | 0.02 | 0.00 | 0.00 | 0.00 | 0.00 | 0.01 |
| Li₂O | 0.0005 | 0.0007 | 0.0005 | 0.0006 | 0.0005 | 0.0005 | 0.0005 | 0.0007 | 0.0008 | 0.0008 |
| Na₂O | 0.0294 | 0.0075 | 0.0246 | 0.0120 | 0.0083 | 0.0198 | 0.0096 | 0.0100 | 0.0079 | 0.0154 |
| K₂O | 0.0019 | 0.0013 | 0.0018 | 0.0013 | 0.0011 | 0.0011 | 0.0014 | 0.0014 | 0.0014 | 0.0012 |
| SnO₂ | 0.2 | 0.2 | 0.2 | 0.2 | 0.2 | 0.2 | 0.2 | 0.2 | 0.2 | 0.2 |
| Na₂O + K₂O | 0.0313 | 0.0088 | 0.0264 | 0.0133 | 0.0094 | 0.0209 | 0.0110 | 0.0114 | 0.0093 | 0.0166 |
| 10 Seconds Later | 141.51 | 48.02 | N.A. | N.A. | N.A. | 125.08 | N.A. | N.A. | N.A. | N.A. |
| Surface Potential [V] | | | | | | | | | | |
| β-OH Value [/mm] | 0.54 | 0.13 | 0.45 | 0.12 | 0.09 | 0.39 | 0.08 | 0.05 | 0.06 | 0.08 |
| Ps [° C.] | 654 | 687 | 708 | 725 | 744 | 742 | 747 | 749 | 746 | 782 |
| Ta [° C.] | 709 | 743 | 768 | 782 | 804 | 802 | 804 | 808 | 806 | 844 |
| Ts [° C.] | 944 | 977 | 1017 | 1007 | 1039 | 1051 | 1034 | 1043 | 1042 | 1084 |
| α [×10⁻⁷/° C.] | 37.8 | 36.8 | 34.8 | 36.3 | 37.7 | 39.3 | 45.4 | 39.0 | 39.1 | 37.9 |
| Density [g/cm³] | 2.459 | 2.521 | 2.466 | 2.551 | 2.589 | 2.617 | 2.643 | 2.638 | 2.686 | 2.668 |
| Young's Modulus [GPa] | 73.0 | 78.0 | 77.0 | 83.0 | 81.7 | 81.0 | 83.3 | 83.4 | 80.0 | 82.7 |
| Specific Young's | 29.7 | 30.9 | 31.2 | 32.5 | 31.6 | 31.0 | 31.5 | 31.6 | 29.8 | 31.0 |
| Modulus[Gpa · cm³/g] | | | | | | | | | | |
| TL [° C.] | 1084 | 1123 | 1174 | 1184 | 1227 | 1225 | 1221 | 1220 | 1213 | 1247 |
| Log η at TL [dPa · s] | 5.7 | 5.6 | 5.5 | 5.2 | 5.2 | 5.5 | 5.2 | 5.3 | 5.3 | 5.5 |
| Temp. at 10^{4.0} dPa · s [° C.] | 1268 | 1285 | 1334 | 1314 | 1361 | 1401 | 1368 | 1365 | 1365 | 1418 |
| Temp. at 10^{8.0} dPa · s [° C.] | 1428 | 1440 | 1497 | 1469 | 1521 | 1574 | 1542 | 1529 | 1528 | 1585 |
| Temp. at 10^{2.5} dPa · s [° C.] | 1532 | 1540 | 1602 | 1567 | 1624 | 1682 | 1654 | 1634 | 1632 | 1688 |

First, a glass batch obtained by formulating glass raw materials to give each of the glass compositions shown in the table was put into a platinum crucible and melted therein at 1600 to 1650° C. for 24 hours. In melting the glass batch, molten glass was stirred with a platinum stirrer to homogenize it. Next, the molten glass was poured onto a carbon plate to form it into a sheet-like shape and then gradually cooled for 30 minutes at a temperature of around the annealing point. Each sample obtained as above was evaluated in terms of 10 seconds later surface potential, β-OH value, strain point Ps, annealing point Ta, softening point Ts, average coefficient α of thermal expansion in a temperature range from 30 to 380° C., density, Young's modulus, specific Young's modulus, liquidus temperature TL, liquidus viscosity log ηatTL, temperature at a high-temperature viscosity of 10^{4.0} dPa·s, temperature at a high-temperature viscosity of 10^{3.0}° dPa·s, and temperature at a high-temperature viscosity of 10^{2.5} dPa·s.

The 10 seconds later surface potential was measured by the method described previously.

The β-OH value is a value calculated by the method described previously.

The strain point Ps, the annealing point Ta, and the softening point Ts are values measured based on the method described in ASTM C336 and C338.

The average coefficient α of thermal expansion in a temperature range from 30 to 380° C. is a value measured with a dilatometer.

The density is a value measured according to the well-known Archimedes' method.

The Young's modulus is a value measured using the well-known resonance method. The specific Young's modulus is a value obtained by dividing the Young's modulus by the density.

The liquidus temperature TL is a value obtained by putting a glass powder having passed through a 30 mesh (500-μm openings) standard sieve and having been retained on a 50 mesh (300-μm openings) sieve into a platinum boat, holding the platinum boat in a temperature-gradient furnace for 24 hours, and measuring the temperature at which crystals (primary phase) precipitate.

The liquidus viscosity log₁₀ηTL is a value obtained by measuring the viscosity of the glass at a liquidus temperature TL by the platinum ball pulling-up method.

The temperatures at high-temperature viscosities of 10^{4.0}° dPa·s, 10^{3.0} dPa·s, and 10^{2.5} dPa·s are values measured by the platinum ball pulling-up method.

As seen from Table 2, the 10 seconds later surface potentials of sample Nos. 1 to 10 were 141. 51 V or less, which shows low chargeability. Therefore, these samples can be considered to be suitably usable as substrates for organic EL displays or the like.

1. A glass substrate containing, as a glass composition in terms of % by mass, 1.7 to less than 9% B₂O₃, 0.01% or less Li₂O, 0.001 to 0.03% Na₂O, 0.0001 to 0.007% K₂O, 0.0011 to 0.035% Na₂O+K₂O, and more than 0 to 0.4% SnO₂.

2. A glass substrate containing, as a glass composition in terms of % by mass, 0.01% or less Li₂O, 0.001 to 0.03% Na₂O, 0.0001 to 0.007% K₂O, and 0.0011 to 0.035% Na₂O+K₂O and having a Young's Modulus of 80 GPa or more.

3. A glass substrate containing, as a glass composition in terms of % by mass, 0.01% or less Li₂O, 0.001 to 0.03% Na₂O, 0.0001 to 0.007% K₂O, 0.0011 to 0.035% Na₂O+K₂O, and 0.1% or less P₂O₅ and having a β-OH value of 0.18/mm or less.

4. A glass substrate containing, as a glass composition in terms of % by mass, 0.01% or less Li₂O, 0.001 to 0.03% Na₂O, 0.0001 to 0.007% K₂O, and 0.0011 to 0.035% Na₂O+K₂O.

5. The glass substrate according to claim 4, further containing as the glass composition 0.1% by mass or less P₂O₅.

6. The glass substrate according to claim 4, having a 10 seconds later surface potential of 1000 V or less in terms of absolute value.

7. The glass substrate according to claim 4, wherein a degree of thermal contraction when subjected to a heat treatment at 500° C. for an hour is 30 ppm or less.

8. The glass substrate according to claim 4, having a strain point of 700° C. or higher.

9. The glass substrate according to claim 4, wherein an average coefficient of thermal expansion in a range from 30 to 380° C. is 45×10⁻⁷/° C. or less.

10. The glass substrate according to claim 4, having a Young's modulus of 80 GPa or more.

11. The glass substrate according to claim 4, having a liquidus viscosity of 10^{4.2} dPa·s or more.

12. The glass substrate according to claim 4, wherein a temperature at 10^{2.5} dPa·s is 1590° C. or lower.

13. The glass substrate according to claim 4, having a β-OH value of 0.18/mm or less.

14. The glass substrate according to claim 4, having a thickness of 0.01 to 1.0 mm.

15. A method for producing a glass substrate, the method comprising producing the glass substrate according to claim 4 by an overflow downdraw method.
